(19) United States
(12) Patent Application Publication
(10) Pub. No.: US 2010/0066358 A1
(43) Pub. Date: Mar. 18, 2010

(54) MAGNETIC SIGNATURE ASSESSMENT

(75) Inventors: Roger Twelvetrees, Rugeley (GB); Emily Cox, Rugeley (GB); Carl Ganderton, Rugeley (GB); Paul Rawlins, Rugeley (GB); Stephen Miles Watson, Stafford (GB)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: ULTRA ELECTRONICS LIMITED, Greenford (GB)

(21) Appl. No.: 12/447,403

(22) PCT Filed: Oct. 26, 2007
(86) PCT No.: PCT/GB07/04086

§ 371 Date: Oct. 15, 2009

(30) Foreign Application Priority Data
Oct. 27, 2006 (GB) 0621461.3

(51) Int. Cl. G01R 33/00

(52) U.S. Cl. 324/260

(57) ABSTRACT

Magnetic signature assessment apparatus for a vehicle comprising sensors for incorporation in the vehicle to measure the magnetic field normal to a closed surface at least approximately bounding the vessel and processing means for calculating from the normal field measurements a scalar magnetic potential outside the surface. Apparatus may be provided on the vehicle to generate a magnetic field to suppress the magnetic signature corresponding to the scalar potential. The invention also extends to corresponding methods and to programs for implementing those methods.

### BACKGROUND

1. Field of the Disclosure

The disclosure generally relates to methods of, and apparatus for, assessing the magnetic signature of a vessel. Once such a signature has been assessed, it is then possible to control or modify the signature in a desired manner.

2. Related Technology

It is important for military vessels on voyage to have the ability to go undetected by surveillance methods which utilize the change in magnetic and electric fields produced by the presence of a vessel. Vessels which are constructed of ferromagnetic material have a magnetic field which is combination of two magnetic artifacts: the induced field and the permanent field. The induced field is proportional to the instantaneous incident field (i.e. the Earth's field). The permanent field changes in complex ways related to the magnetic history of the vessel and is dependent on the stress on the hull.

The general concept of degaussing is to reduce the magnetic signature of a vessel by installing a number of direct current carrying coils on board the vessel. In principle, by applying suitable currents to these coils, a magnetic field can be generated which matches the ferromagnetic field associated with the vessel, but with opposite sign, thus reducing the signature to zero. In practice of course, this ideal zero field is not actually achievable and the degaussing problem becomes one of optimizing/minimizing the field with respect to some appropriate measure. Methods have been developed over the years to accomplish this and are generally very successful at reducing the field to the required levels for a limited period of time.

The performance of a degaussing technique is typically assessed using a degaussing range, which typically consists of an array of magnetometers on the sea bed which measure the magnetic signature of a vessel as it traverses the range. The data collected from a degaussing range is also used to calculate the optimum currents for the degaussing coils. These current settings are then kept for the duration of the voyage until the vessel's next visit to a degaussing range. This is known as open loop degaussing (OLDG).

It is known that, whilst at sea, and particularly in the case of submersibles whilst diving, the permanent magnetic field of the vessel can change significantly enough so that the signature is no longer within acceptable levels. An OLDG system cannot respond to this, and so the currents will be kept the same until the vessel is ranged again, which in itself is a costly and time consuming process.

### SUMMARY

In one embodiment, a magnetic signature assessment apparatus for a vehicle includes sensors for incorporation in the vehicle to measure the magnetic field normal to a closed surface at least approximately bounding the vehicle and processing means for calculating from the normal field measurements a scalar magnetic potential outside the surface.

In another embodiment, a method of assessing the magnetic signature of a vehicle includes measuring the magnetic field normal to a closed surface at least approximately bounding the vehicle using sensors incorporated in the vehicle and calculating from the normal field measurements a scalar magnetic potential outside the surface.

In certain embodiments, the no al field measurements are interpolated to provide finer coverage of the closed surface.

In certain embodiments, the scalar magnetic potential is used to estimate the magnetic field outside the surface such that degaussing equipment can be tuned to suppress that magnetic field.

### BRIEF DESCRIPTION OF THE DRAWINGS

By way of example only, certain embodiments of the invention will now be described by reference to the accompanying FIGURES, in which:

FIG. 1 is a schematic diagram of a cross-section of a submarine.

### DETAILED DESCRIPTION

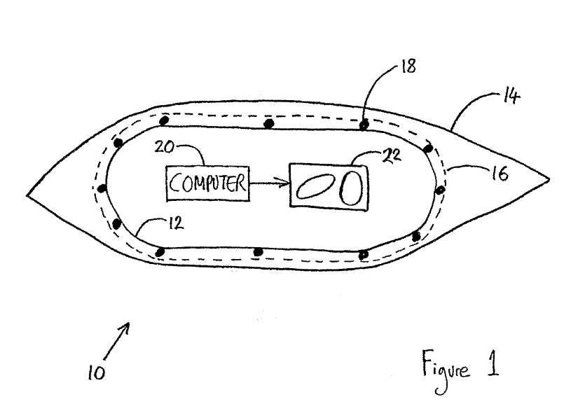

FIG. 1 shows across section through a submarine 10. The FIGURE shows only those parts of the submarine 10 that are necessary for describing the invention. The submarine 10 comprises a pressure hull 12 mounted within a casing 14. The outer surface of the pressure hull 12 is studded at intervals with magnetic field sensors shown as black circles, e.g. 18. Each of the magnetic field sensors is arranged to measure the normal component of the magnetic field that is present at the location of the sensor concerned. The submarine 10, carries a set of degaussing coils 22 that can be energized appropriately in an attempt to minimize the magnetic signature of the submarine as would be perceived by, say, a magnetic mine in some zone, typically the sea bed, beyond the submarine 10. The construction, arrangement and operation of degaussing coils is well known in this field and will therefore not be discussed further.

The normal magnetic field measurements produced by the sensors are transmitted to a computer 20, which controls the energization of the degaussing coils 22. The computer 20 uses the normal magnetic field measurements to estimate the magnetic signature of the submarine 10 and then determines the output of a set of degaussing coils 22 in order to minimize the magnetic signature. Whenever desired, the computer 20 can read the outputs of the magnetic field sensors and adjust the output of the degaussing coils 22 in an effort to maintain the minimization of the submarine's magnetic signature. Therefore, the degaussing system employed by the submarine 10 is called a closed loop degaussing (CLDG) system.

In general terms, the computer 20 calculates from the normal magnetic field measurements the scalar magnetic potential outside a notional closed surface Ω that envelops the pressure hull 12. It is assumed that surface Ω encloses all or substantially all of the ferromagnetic material associated with or forming part of the submarine 10. Vector \vec{r} shall be taken to specify a point in the region outside Ω and vector \vec{r}′ shall be taken to specify a point on surface Ω. In FIG. 1, the surface Ω is represented, in cross-section, by dashed line 16. In practice, Ω is made a close fit to the pressure hull 12 with the magnetic field sensors lying substantially in the surface Ω. Then, from the scalar magnetic potential, the computer 20 calculates the magnetic field \vec{B}(\vec{r}) in the space outside the surface Ω. Then, the computer 20 controls the degaussing coils 22 so that they minimize the magnetic field \vec{B}(\vec{r}) that is the magnetic signature of the submarine 10. This so-called CLDG algorithm will shortly be described in more detail.

The aforementioned minimization of the magnetic field \vec{B}(\vec{r}) would occur over all space outside surface Ω if the arrangement of the coils 22 were perfect. However, in practice, there is limited space to accommodate the degaussing coils so compromises must inevitably be made in terms of their number, location and orientation within the submarine 10. This means that in practice the minimization of \vec{B}(\vec{r}) will not be perfect throughout the space \vec{r}. In practical applications, then, the system will aim to minimize the magnetic signature in locations where threats are expected, e.g. at the sea bed.

For the purposes of the CLDG algorithm, it is assumed that the measurements made by the magnetic field sensors on the pressure hull are measurements of the normal component of the magnetic field at locations on the surface Ω, \vec{Bₙ}(\vec{r}′). The computer 20 interpolates the \vec{Bₙ}(\vec{r}) measurements for additional points on the surface Ω using the magnetic field data provided by the sensors located on the pressure hull (it will be recalled that the algorithm assumes that the magnetic field sensors on the pressure hull are coincident with the Ω). The creation of software to increase the number of \vec{B}ₙ(\vec{r}′) measurements by interpolation is entirely within the capabilities of the skilled person and needs no further explanation here.

The magnetic field normal to the surface Ω, \vec{B}ₙ(\vec{r}′), is related to the scalar magnetic potential φ(\vec{r}) outside the surface Ω by the following equations:

$${r}^{->} ∈ Ω ∖ δ Ω \text{:} φ ( {r}^{->} ) = - \frac{1}{4 π} {\int }_{δ Ω} [ \begin{matrix}\frac{1}{\vert {r}^{->} - {{r}^{′}}^{->} \vert} \frac{{{B}^{->}}_{n} ( {{r}^{′}}^{->} )}{μ} + \\ φ ( {{r}^{′}}^{->} ) \frac{δ}{δ n} ( \frac{1}{\vert {r}^{->} - {{r}^{′}}^{->} \vert} )\end{matrix} ] d {S}^{′} - ← \\ {r}^{->} ∈ δ Ω \text{:} \frac{φ ( {r}^{->} )}{2} = - \frac{1}{4 π} {\int }_{δ Ω} [ \begin{matrix}\frac{1}{\vert {r}^{->} - {{r}^{′}}^{->} \vert} \frac{{{B}^{->}}_{n} ( {{r}^{′}}^{->} )}{μ} + \\ φ ( {{r}^{′}}^{->} ) \frac{δ}{δ n} ( \frac{1}{\vert {r}^{->} - {{r}^{′}}^{->} \vert} )\end{matrix} ] d {S}^{′} - ↑$$

Equation [symbol] is the solution for space outside the surface Ω and excluding Ω itself and equation ℑ is the solution for points on Ω. In these equations:

\vec{r}′ is a vector specifying a point on surface Ω.
\vec{r} is a vector specifying a point in the space beyond surface Ω.
dS′ indicates that the integral is to be performed over the surface Ω.
μ is the permeability of the medium beyond surface Ω.
\vec{B}ₙ(\vec{r}′) is the normal component of the magnetic field at point \vec{r}′ on surface Ω, with positive \vec{B}ₙ(\vec{r}′) being taken to point into Ω.

The CLDG algorithm then determines an array of φ(\vec{r}) values for an array of points on and beyond Ω using equations [symbol] and ℑ respectively. The array of φ(\vec{r}) values is then used to calculate \vec{B}(\vec{r}) using the following equation:

\vec{B}(\vec{r})=−μ∇φ(\vec{r}). —→

As will be apparent to the skilled person, equation [symbol] can readily be solved, given the pool of φ(\vec{r}) values, using finite element analysis techniques, which techniques will be readily understood by the skilled person and hich therefore are not described further here.

Once \vec{B}(\vec{r}) deduced, the degaussing coils 22 can be set appropriately so as to suppress the magnetic signature.

A derivation of equations ← and ↑ describing the scalar magnetic potential φ(\vec{r}) is provided in an annex to the description.

In practice, at least some part of the ferromagnetic material of the submarine 10 lies outside the surface Ω. The greater the amount of ferromagnetic material protruding beyond Ω, the less effective the computer's suppression of the magnetic signature will be.

In the embodiment shown in FIG. 1, the sensors 18 are mounted on the pressure hull. In variants of this arrangement the sensors 18 can instead be located on the casing 14 or it may even be the case that some of the sensors are on the casing whilst other are mounted on the pressure hull. All that is important is that the sensors 18 provide useful magnetic field information for a surface bounding at least the majority of the submarine's ferromagnetic material.

In another embodiment, all or part of one of the degaussing coils 22 lies outside the surface Ω. This means that there is a source of magnetic flux in the zone beyond surface Ω, which renders the derivation of equations ← and ↑ invalid. However, because the flux emanating from the coil in question is well known, and because the induced effect of that coil on the vessel can be measured on a degaussing range, a correction for the presence of the outlying coil can be made using the principle of superposition of magnetic fields. The contribution from the outlying coil is subtracted from the normal field measurement locations, and the appropriate keel signature due to the coil added.

In other embodiments, more than one of the degaussing coils 22 lies at least partially outside the surface Ω. However a plurality of outlying degaussing coils is in principle handled in the same manner as for one such coil so therefore this embodiment will not be described in further detail.

While the present invention has been described with reference to specific examples, which are intended to be illustrative only and not to be limiting of the invention, it will be apparent to those of ordinary skill in the art that changes, additions or deletions may be made to the disclosed embodiments without departing from the spirit and scope of the invention.

1. Magnetic signature assessment apparatus for a vehicle comprising sensors for incorporation in the vehicle to measure the magnetic field normal to a closed surface at least approximately bounding the vehicle and processing means for calculating from the normal field measurements a scalar magnetic potential outside the surface.

2. Apparatus according to claim 1, wherein the processing means is arranged to interpolate the normal field measurements to a finer mesh of normal field values over the surface.

3. Magnetic signature suppression apparatus for a vehicle, comprising the assessment apparatus of claim 1 for calculating a scalar magnetic potential and further comprising means for incorporation in the vehicle to generate a magnetic field to suppress the magnetic signature corresponding to the scalar potential.

4. Apparatus according to claim 3, wherein the magnetic field generating means is at least partially located outside said surface and the processing means is arranged to compensate for this in deduction of the scalar magnetic potential.

5. A method of assessing the magnetic signature of a vehicle, the method comprising measuring the magnetic field normal to a closed surface at least approximately bounding the vehicle using sensors incorporated in the vehicle and calculating from the normal field measurements a scalar magnetic potential outside the surface.

6. A method according to claim 5, further comprising the step of interpolating the normal field measurements to a finer resolution of values over the surface.

7. A method of suppressing the magnetic signature of a vehicle, the method comprising the assessment method of claim 5 for calculating a scalar magnetic potential and further comprising generating a magnetic field on board the vehicle to suppress the magnetic signature corresponding to the scalar potential.

8. A method according to claim 7, wherein the means for generating the magnetic field lies at least partially outside said surface and the calculation step is arranged to compensate for this in deduction of the scalar magnetic potential.

9. A program for causing data processing equipment to perform the method of claim 5.

10-11. (canceled)
